(19) United States
(12) Patent Application Publication
(10) Pub. No.: US 2002/0047732 A1
(43) Pub. Date: Apr. 25, 2002

(54) Peak-hold circuit with variable time constant

(76) Inventor: Hiroji Akahori, Tokyo (JP)

Correspondence Address: RABIN & CHAMPAGNE, PC, 1101 14TH STREET, NW, SUITE 500, WASHINGTON, DC, 20005, US

(21) Appl. No.: 09/951,222

(22) Filed: Sep. 14, 2001

(30) Foreign Application Priority Data
Oct. 20, 2000 (JP) 2000-320902

(51) Int. Cl. H03K 5/00

(52) U.S. Cl. 327/93

(57) ABSTRACT

A peak-hold circuit that receives an input signal in intermittent bursts has a diode and a capacitor coupled so as to hold the peak input level of each burst. The circuit also has a unit through which the capacitor can discharge with a controllable time constant. The time constant can be controlled according to the expected rate of variation of the input signal level, to permit tracking of peak level variations from burst to burst. Alternatively, the time constant can be increased during bursts to assure stable holding of the peak level, and decreased between bursts to permit tracking of burst-to-burst variations.

### BACKGROUND OF THE INVENTION

The present invention relates to a circuit for holding the peak level of a signal that is received in intermittent bursts; the invention is useful in automatic gain control of the received signal.

Automatic gain control (AGC) of signals received in intermittent burst is necessary in, for example, the on-board equipment (radio transponders) mounted in vehicles in certain electronic toll collection (ETC) systems. As shown in FIG. 17, the AGC circuit commonly employed includes an AGC amplifier 11, a detector 12, a low-pass filter (LPF) 13, a peak-hold circuit 14, and a level adjustment circuit 15.

The signal input to the AGC circuit is a carrier wave modulated by amplitude-shift keying (ASK), transmitted from a roadside beacon to the moving vehicle. The input signal is amplified by the AGC amplifier 11, then detected by the detector 12 to obtain a demodulated signal, referred to below as an ASK signal. This ASK signal is the output of the AGC circuit. The ASK signal is also filtered by the low-pass filter 13, which removes high frequency components, then supplied to the peak-hold circuit 14, which temporarily holds the peak level of the filtered ASK signal. From the peak level, the level adjustment circuit 15 generates an AGC control voltage that controls the gain of the AGC amplifier 11. A feedback loop is thereby formed that keeps the output level of the AGC amplifier 11 constant, even if the input level of the ASK signal varies: when the input level of the ASK signal drops, so does the peak level held by the peak-hold circuit 14, causing the level adjustment circuit 15 to reduce the AGC control voltage and increase the gain of the AGC amplifier 11; conversely, when the input level of the ASK signal rises, its peak level and the AGC control voltage also rise, reducing the gain of the AGC amplifier 11.

FIG. 18 shows the internal structure of a conventional peak-hold circuit 10, which may be used as the peak-hold circuit 14 in FIG. 17. The conventional peak-hold circuit 10 comprises a capacitor C1, a diode D1, resistors R1, R2, R3, and a pair of operational amplifiers OP1, OP2. The peak-holding function is provided by diode D1, capacitor C1, and resistor R3. Node NO is the input node of this peak-holding section; node N1 is the output node.

FIGS. 19A to 19D show waveforms illustrating the input and output signals of the low-pass filter 13 and peak-hold circuit 10. FIG. 19A shows the demodulated ASK signal input to the low-pass filter 13 from the detector 12. The ASK signal is received in intermittent bursts with data bits D grouped into frames F, referred to below as ASK frames, each frame constituting a burst. FIG. 19B shows the filtered ASK signal output from the low-pass filter 13 to the peak-hold circuit. FIG. 19C and 19D show two examples of the output of the peak-hold circuit 10.

The ASK signal shown in FIG. 19A is the baseband signal. A frame F comprises a plurality of data bits D, some of which are high while others are low. These frames are separated by intervals in which no data bits are present. The low-pass filter 13 smoothes out the bits D by removing high frequency components, and maintains low-level output during the intervals between frames F, as shown in FIG. 19B. The resulting signal is supplied to the peak-hold circuit 10 shown in FIG. 18 (the peak-hold circuit 14 in FIG. 17).

The operational amplifier OP1 in FIG. 18 controls the potential of node NO according to the difference between the input signal received from the low-pass filter 13, shown in FIG. 19B, and the output signal of the peak-hold circuit, shown in FIG. 19C or 19D. If the output signal is at substantially zero volts at the beginning of an ASK frame F, for example, then at the first high bit in frame F, operational amplifier OP1 sharply raises the potential of node NO, diode D1 turns on, and the current conducted by diode D1 swiftly charges capacitor C1, thereby raising the output signal level (the potential of node N1). When the output signal level reaches the input signal level, operational amplifier OP1 sharply reduces the potential of node NO and diode D1 turns off. The result is that capacitor C1 is charged to and holds the peak level of the input signal. This peak level is output by operational amplifier OP2 to the level adjustment circuit 15.

Capacitor C1 discharges slightly through resistor R3 during low data bits in the frame F, but is recharged to the peak level at each high data bit. After the end of the frame F, however, when high data bits stop arriving, the charge stored in capacitor C1 discharges through resistor R3 and is not replenished, causing the output signal level to fall. In the conventional peak-hold circuit 10, the time constant of the discharge is c1×r3, where c1 is the capacitance of capacitor C1 and r3 is the resistance of resistor R3. Capacitor C1 discharges at a rate proportional to this time constant.

As the moving vehicle passes through the beacon communication zone, the electric field level of the ASK signal bursts received by the on-board equipment first increases, then decreases. The signal level of the received signal thus changes from one burst (one frame) to another. The rate of change depends on the vehicle's speed, which may vary from, say, twenty or thirty kilometers per hour to over one hundred kilometers per hour.

The AGC feedback loop must be able to control the gain of the AGC amplifier 11 according to the varying level of each frame F. During an individual frame F, the peak-hold circuit 10 must also be able to hold the peak level of the frame despite the presence of low-level data bits in the frame. Thus although capacitor C1 in the peak-hold circuit 10 is charged almost instantly through diode D1 when the potential level of the input node NO exceeds the potential of node N1, capacitor C1 must not discharge too quickly through resistor R3 when the potential level of the input node NO is less than the potential level of node N1.

If F(n) and F(n+1) are two consecutive ASK frames, and if frame F(n+1) is received at a higher signal level than frame F(n), then after holding the peak level of frame F(n), the peak-hold circuit 10 will experience no difficulty in tracking to the higher level of frame F(n+1). At the first high data bit in frame F(N+1), the input signal level of the peak-hold circuit will exceed the output signal level, so diode D1 will turn on and capacitor C1 will quickly charge to the higher level of the input signal.

If frame F(n+1) is received at a lower signal level than frame F(n), however, then depending on the time constant mentioned above, when frame F(n+1) begins, the potential level still, held at node N1 may exceed the peak potential level of frame F(n+1). In this case diode D1 fails to turn on, so the peak-hold circuit 10 cannot track the peak level of frame F(n+1); the output signal level of the peak-hold circuit 10 remains higher than that peak level. In order for the peak-hold circuit 10 to track the new peak level of frame F(n+1), the potential of node N1 must fall below that new peak level, so that diode D1 can turn on, after which the potential of node N1 will rise to the new peak level.

FIG. 19C illustrates the case in which the time constant c1×r3 is small enough for capacitor C1 to discharge almost completely between frames. The peak-hold circuit 10 is able to track all frame-to-frame variations. Within each frame, however, capacitor C1 discharges significantly during the low data bit intervals, causing considerable unevenness in the peak-hold output signal. This unevenness (voltage ripple) has a destabilizing effect on automatic gain control within the frame.

FIG. 19D illustrates the case in which the time constant c1×r3 is so large that capacitor C1 hardly discharges at all between frames. Although the output signal is very stable within each frame, the peak-hold circuit 10 is only able to track frame-to-frame variations in the rising direction; it cannot track downward variations.

In order to obtain good receiving characteristics, such as a low bit error rate, it is desirable to track all frame-to-frame variations in the received signal level, so that the gain of the AGC amplifier 11 can be appropriately controlled, but it is also desirable to stabilize the output of the peak-hold circuit 10 during each frame, so that the AGC amplifier gain does not fluctuate significantly in response to low data bits in the frame.

Since the time constant c1×r3 is the same during frames as between frames, there is a tradeoff between these requisites. The time constant must be small enough to permit the tracking of all frame-to-frame level variations, but within that range, it is desirable for the time constant to be as large as possible, in order to stabilize the output of the peak-hold circuit within the individual frames.

The optimum value of the time constant is thus the largest value that permits tracking of all frame-to-frame variations, but the optimum value is difficult to specify, because the rate of frame-to-frame variations depends on the speed of the vehicle. With a conventional peak-hold circuit, in which the time constant has a fixed value, the time constant can be optimal for only one vehicle speed. At other speeds, the time constant is not optimal, and receiving characteristics suffer accordingly.

### SUMMARY OF THE INVENTION

An object of the present invention is to provide a peak-hold circuit with a time constant that can be optimized for both stable peak-level output and reliable tracking of variations in the peak level.

The invented peak-hold circuit receives an input signal in intermittent bursts. The input signal is supplied to the anode of a diode. A capacitor is coupled between the cathode of the diode and ground to hold the peak level of the input signal. A fixed resistor may also be coupled between the cathode of the diode and ground.

In one aspect of the invention, a variable resistance unit is coupled between the cathode of the diode (D1) and ground, providing an electrical resistance that varies according to a control signal. The control signal is generated by a discharge control unit that receives information indicating the expected rate of variation of the input signal level. As this expected rate increases, the discharge control unit preferably decreases the resistance of the variable resistance unit.

In this aspect of the invention, the discharge resistance of the capacitor, hence the discharge time constant, varies according to the expected rate of variation of the input signal level, and can therefore be optimized according to that rate.

In another aspect of the invention, a discharge unit, coupled between the cathode of the diode and ground, opens and closes a discharge path for the capacitor in response to a control signal. The control signal is generated by a discharge control unit that receives information indicating the timing of the intermittent bursts of the input signal. The discharge path is opened, so that it does not conduct, during the intermittent bursts.

In this aspect of the invention, the capacitor discharges with a first time constant when the discharge path is open, and with a second time constant when the discharge path is closed, the second time constant being smaller than the first time constant. The first time constant can be optimized for stable peak-holding operation during the intermittent bursts. The second time constant can be optimized for adequate tracking of variations in the input signal level between bursts.

### BRIEF DESCRIPTION OF THE DRAWINGS

In the attached drawings:

FIG. 1 is a schematic diagram of a peak-hold circuit illustrating a first embodiment of the invention;

FIG. 2 is a block diagram of the discharge control circuit in FIG. 1, showing associated signal waveforms;

FIG. 3 is a schematic diagram of a peak-hold circuit illustrating a second embodiment of the invention;

FIG. 4 is a block diagram of the discharge control circuit in FIG. 3, showing associated signal waveforms;

FIG. 5 is a schematic diagram of a peak-hold circuit illustrating a third embodiment of the invention;

FIG. 6 is a block diagram of the discharge control circuit in FIG. 5, showing associated signal waveforms;

FIG. 7 is a schematic diagram of a peak-hold circuit illustrating a fourth embodiment of the invention;

FIG. 8 is a waveform diagram illustrating the operation of the discharge control circuit in FIG. 7;

FIG. 9A is a block diagram of the discharge control circuit in FIG. 7;

FIGS. 9B, 9C, and 9D are waveform diagrams illustrating the operation of the discharge control circuit in FIG. 9A;

FIG. 10 is a schematic diagram of a peak-hold circuit illustrating a fifth embodiment of the invention;

FIG. 11 is a waveform diagram illustrating the operation of the fifth embodiment;

FIG. 12 is a block diagram of the discharge control circuit in FIG. 10;

FIG. 13 is a schematic diagram of a peak-hold circuit illustrating a sixth embodiment of the invention;

FIG. 14 is a schematic diagram of a peak-hold circuit illustrating a seventh embodiment of the invention;

FIG. 15 is a schematic diagram of a peak-hold circuit illustrating an eighth embodiment of the invention;

FIG. 16 is a block diagram of the discharge control circuit in FIG. 15;

FIG. 17 is a block diagram of an AGC circuit;

FIG. 18 is a schematic diagram of a conventional peak-hold circuit;

FIG. 19A is a waveform diagram illustrating a demodulated ASK signal;

FIG. 19B is a waveform illustrating the filtered ASK signal input to the peak-hold circuit in FIG. 17; and

FIGS. 19C and 19D are waveform diagrams illustrating the output of the conventional peak-hold circuit in FIG. 18.

### DETAILED DESCRIPTION OF THE INVENTION

Embodiments of the invention will be described with reference to the attached drawings. In the descriptions, it will be assumed that the embodiments are used in on-board equipment mounted in vehicles in an electronic toll collection system.

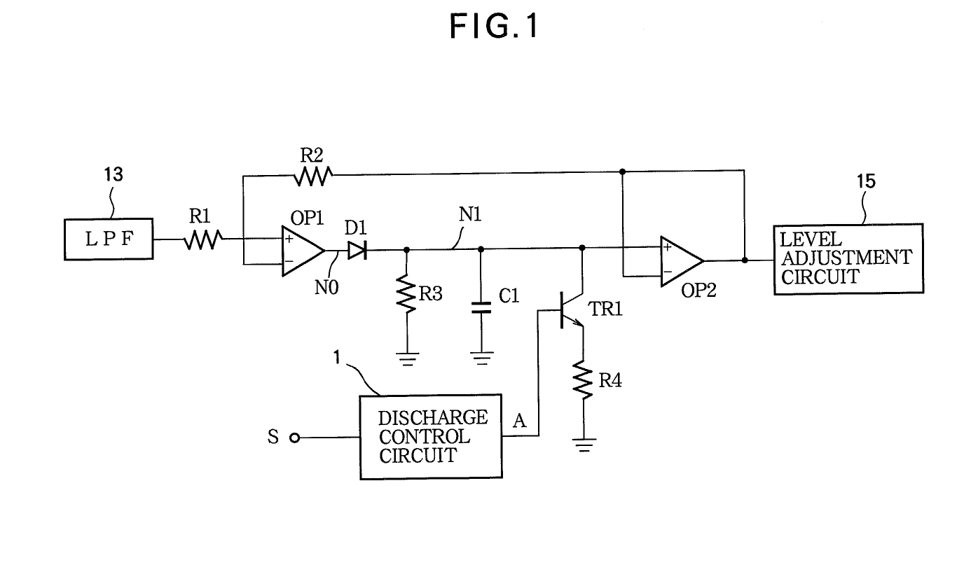

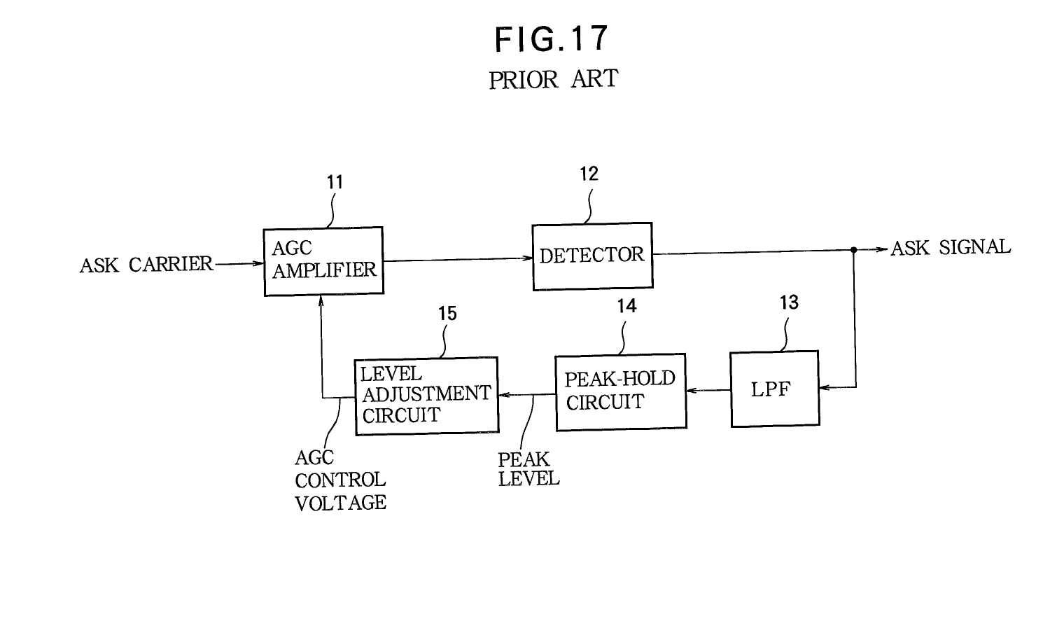

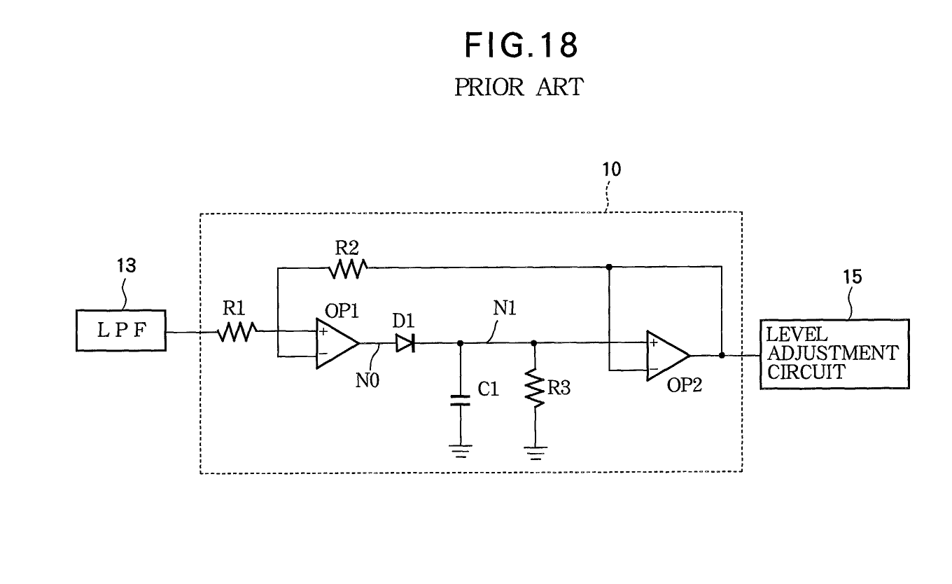

Referring to FIG. 1, the first embodiment is a peak-hold circuit comprising a capacitor C1, a diode D1, an input amplifier OP1, an output amplifier OP2, resistors R1, R2, R3, R4, a bipolar transistor TR1, and a discharge control circuit 1. This circuit can be used as the peak-hold circuit 14 in FIG. 17, receiving a signal from the low-pass filter 13 and providing an output signal to the level adjustment circuit 15, as shown in that drawing. The peak-holding function is provided by the diode D1, capacitor C1, and resistor R3. Transistor TR1 and resistor R4 form a variable resistance unit. This peak-hold circuit is accordingly derived from the conventional peak-hold circuit 10 by adding the variable resistance unit and the discharge control circuit 1.

The input amplifier OP1 has an output terminal connected to node NO, a non-inverting input terminal coupled through resistor R1 to the output terminal of the low-pass filter 13, and an inverting input terminal coupled through resistor R2 to the output terminal and inverting input terminal of the output amplifier OP2. The output amplifier OP2 operates as a voltage follower, its non-inverting input terminal being connected to node N1, its inverting input terminal being connected to its output terminal, and its output terminal being connected to the input terminal of the level adjustment circuit 15.

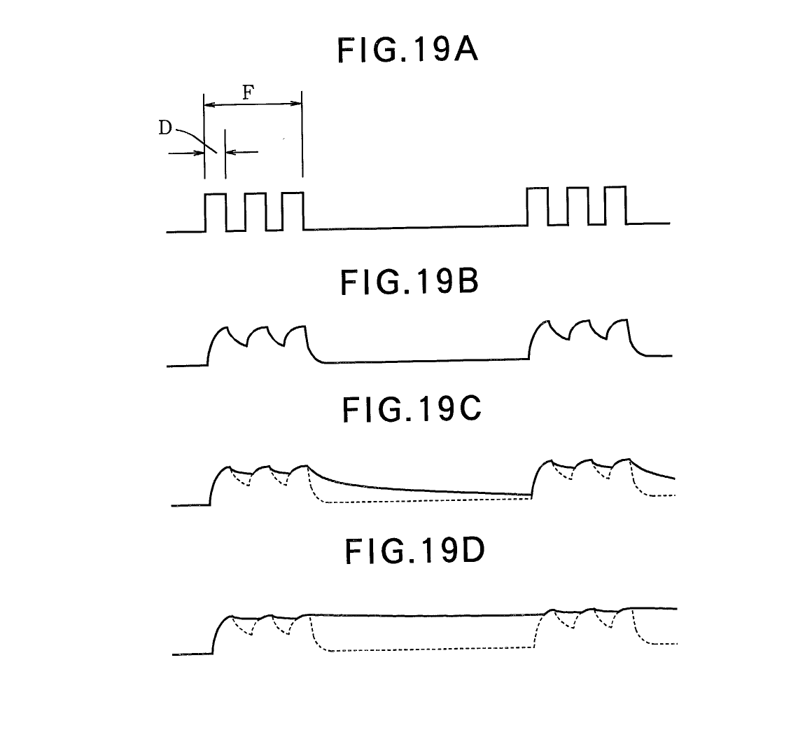

The non-inverting input terminal of the input amplifier OP1 receives the filtered ASK signal from the low-pass filter 13 through resistor R1. This input signal is the ASK signal shown in FIG. 19A output by the detector 12 in FIG. 17, filtered to remove high-frequency components as shown in FIG. 19B. The inverting input terminal of the input amplifier OP1 receives the output signal of the peak-hold circuit through resistor R2. The potential of node NO varies with the difference between the input and output signals. The output signal, which has the same potential as node N1, is supplied to the level adjustment circuit 15 as a feedback signal to control the gain of the AGC amplifier 11.

In the peak-hold section, node NO is the anode node and node N1 is the cathode node of diode D1. Node NO is also the peak-hold input node, being coupled to the output terminal of the input amplifier OP1, while node N1 is the peak-hold output node. Capacitor C1 and resistor R3 are coupled in parallel between node N1 and ground, thus being coupled in parallel between the cathode of diode D1 and ground.

The variable resistance unit (bipolar transistor TR1 and resistor R4) is coupled in parallel with capacitor C1 and resistor R3 between node N1 and ground. In the variable resistance unit, transistor TR1 has its collector electrode coupled to node N1, its emitter electrode coupled through resistor R4 to ground, and its base electrode coupled to receive base current A (control signal current) from the discharge control circuit 1. The resistance between the emitter and collector of transistor TR1 varies according to the base current A. The resistance of the variable resistance unit thus varies according to the control signal output by the discharge control circuit 1.

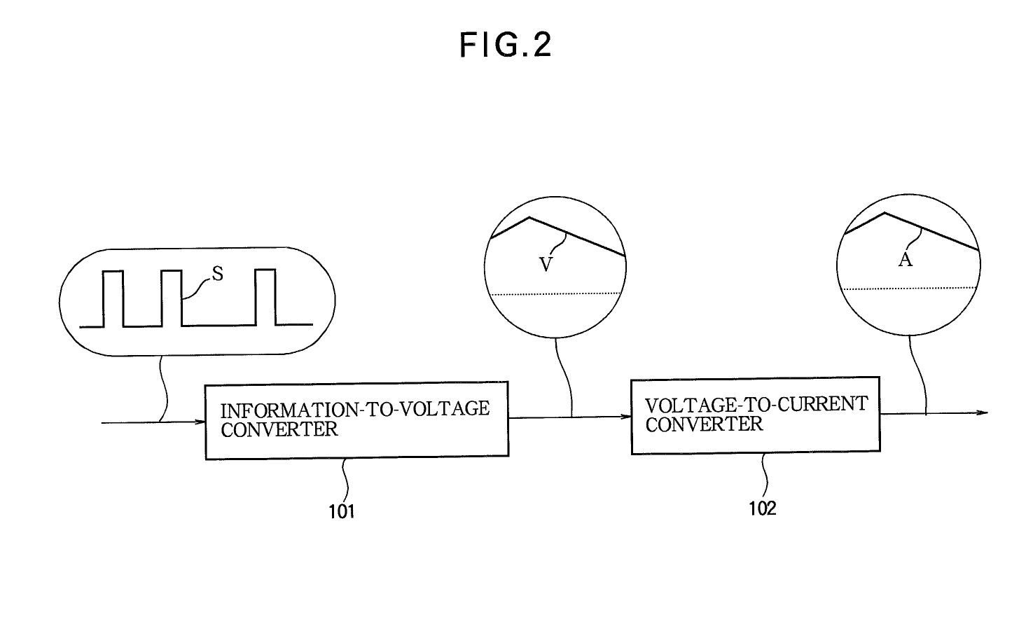

The discharge control circuit 1 generates the control signal A according to vehicle speed information S received from the vehicle, so as to reduce the resistance of the variable resistance unit as the vehicle speed increases. The vehicle speed information S indicates the expected rate of frame-to-frame variation in the ASK signal level; the faster the vehicle is moving, the greater the variations are likely to be. As shown in FIG. 2, the discharge control circuit 1 comprises an information-to-voltage converter 101 and a voltage-to-current converter 102.

The information-to-voltage converter 101 generates a voltage V responsive to the vehicle speed information S. The value of this voltage V increases with increasing vehicle speed. The vehicle speed information S may be received as, for example, a pulse signal indicating revolutions of the vehicle's engine or a wheel. As the vehicle speed increases, the interval between consecutive pulses decreases. Alternatively, some other type of information indicating vehicle speed may be received. Methods of converting pulse signals and other types of information to a voltage signal are well known, so a detailed description of the information-to-voltage converter 101 will be omitted.

The voltage-to-current converter 102 generates an output current A responsive to the voltage V, and supplies this current A as a control signal to the base electrode of transistor TR1. The value of the current A increases with increasing voltage V, thus with increasing vehicle speed. Accordingly, as the vehicle speed increases, the resistance between the emitter and collector of transistor TR1 decreases, and so the resistance of the variable resistance unit decreases.

The first embodiment operates as follows. When the input signal level exceeds the output signal level, as may occur during high bits in an ASK frame, the input amplifier OP1 raises the potential of the peak-hold input node NO, diode D1 turns on, and capacitor C1 rapidly charges. In this way, capacitor C1 soon reaches the peak potential of the input signal in the ASK frame. When the input signal level is equal to or less than the output signal level, the input amplifier OPT reduces the potential of the peak-hold input node NO, turning off diode D1, so capacitor C1 does not charge beyond the peak potential of the ASK frame. The peak potential is held by capacitor C1 at node N1, and output by the output amplifier OP2 to the level adjustment circuit 15.

At the end of the ASK frame the input signal falls to a low level (e.g., ground level) and stays there until the next frame. The input amplifier OP1 holds the potential of the peak-hold input node NO low enough to keep diode D1 turned off, and capacitor C1 discharges through both resistor R3 and the variable resistance unit (bipolar transistor TR1 and resistor R4), causing the potential of node N1 to fall. The same discharge also takes place when low data bits are input during the ASK frame.

Since resistor R3 is coupled in parallel with the variable resistance unit, the discharge resistance Rdis of capacitor C1 can be calculated as follows in terms of the resistance r3 of resistor R3, the resistance r4 of resistor R4, and the emitter-collector resistance rec of transistor TR1.

Rdis1={r3×(r4+rec)}/(r3 +r4 +rec)

The discharge time constant Tdis of capacitor C1 is given by the following equation, in which c1 is the capacitance of capacitor C1.

Tdis=c1×{r3×(r4+rec)}/(r3+r4+rec)

The discharge time of capacitor C1 depends on this time constant Tdis.

As explained above, the information-to-voltage converter 101 in the discharge control circuit 1 generates a voltage V responsive to the speed information received from the vehicle. The voltage-to-current converter 102 supplies a current A, responsive to the voltage V, to the base electrode of transistor TR1. As the vehicle speed increases, the base current A increases and the emitter-collector resistance rec of transistor TR1 decreases.

If transistor TR1 is an ideal bipolar transistor, the discharge resistance Rdis and discharge time Tdis of capacitor C1 vary within the following ranges. Both Rdis and Tdis decrease as the vehicle speed increases, and increase as the vehicle speed decreases.

(r3×r4)/(r3+r4)≦Rdis≦r3

c1×(r3×r4)/(r3+r4)≦Tdis≦c1×r3

Therefore, when the vehicle is moving rapidly and the level of the ASK signal tends to vary greatly from one frame to the next, capacitor C1 discharges comparatively quickly. Conversely, when the vehicle is moving slowly and the level of the ASK signal tends to vary less from one frame to the next, capacitor C1 discharges comparatively slowly.

By providing the variable resistance unit and a discharge control circuit 1 that generates a control signal A responsive to the vehicle speed, accordingly, the first embodiment enables the discharge time constant Tdis of capacitor C1 to decrease as the amount of frame-to-frame variation in the ASK signal level increases. The time constant Tdis can therefore be set to the optimal value (the maximum value enabling frame-to-frame variations to be tracked) for all vehicle speeds, if suitable resistance values are selected and the control signal A is generated in a suitable way. Optimal receiving characteristics can then be obtained at all vehicle speeds.

In a variation of the first embodiment, resistor R3 is eliminated (so that r3=∞). The discharge resistance Rdis of capacitor C1 then varies in the following range.

r4≦Rdis≦

The variation of Rdis is still responsive to the vehicle speed, thus to the rate of frame-to-frame variation in the ASK signal level, so similar effects are obtained.

In another variation, resistor R4 is eliminated (so that r4=0). The discharge resistance Rdis of capacitor C1 then varies in the following range.

0≦Rdis≦r3

Since the discharge resistance Rdis can be reduced to substantially zero, capacitor C1 can be discharged very quickly.

In another variation, both resistors R3 and R4 are eliminated. The discharge resistance Rdis of capacitor C1 varies in the following range.

0≦Rdis≦

The variation of Rdis is still responsive to the vehicle speed, so similar effects are obtained.

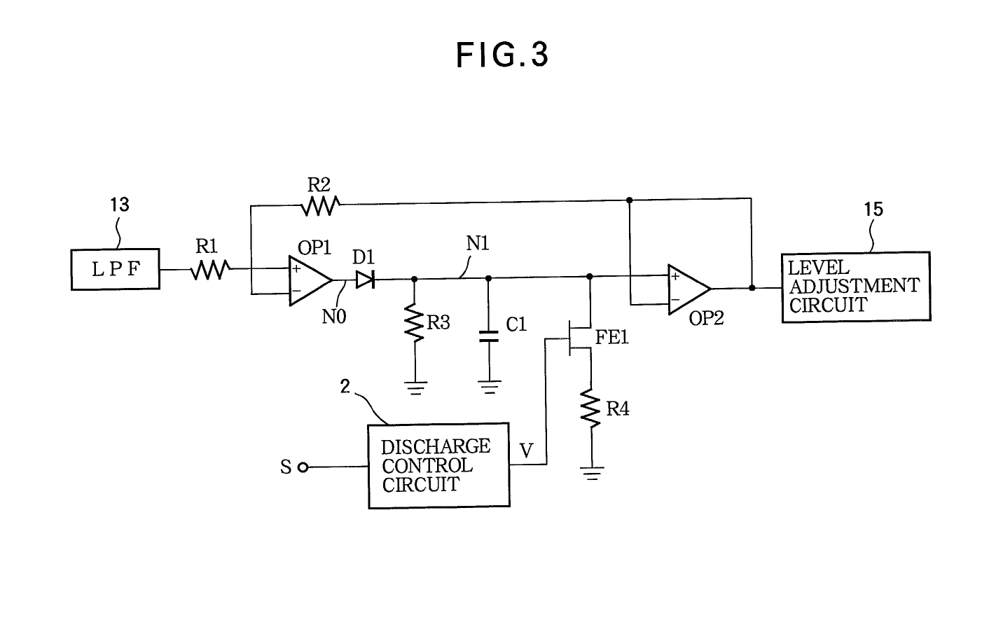

The second embodiment is the peak-hold circuit shown in FIG. 3, which can also be used as the peak-hold circuit 14 in the AGC circuit in FIG. 17.

The capacitor C1, diode D1, input amplifier OP1, output amplifier OP2, and resistors R1, R2, R3, R4 in FIG. 3 are similar to the corresponding elements in FIG. 1. The discharge control circuit 2 in FIG. 3 controls a field-effect transistor FE1 that, together with resistor R4, forms the variable resistance unit. This peak-hold circuit is derived from the conventional peak-hold circuit 10 by adding the variable resistance unit and the discharge control circuit 2. It is also derivable from the first embodiment by replacement of the bipolar transistor TR1 with the field-effect transistor FE1, and simplification of the discharge control circuit.

The variable resistance unit (field-effect transistor FE1 and resistor R4) is coupled in parallel with capacitor C1 and resistor R3 between node N1 and ground. In the variable resistance unit, transistor FE1 has its drain electrode coupled to node N1, its source electrode coupled through resistor R4 to ground, and its gate electrode coupled to receive a voltage signal V (control signal) from the discharge control circuit 2. The resistance between the source and drain of transistor FE1 varies according to this gate voltage V. Thus, the resistance of the variable resistance unit varies according to the control signal V output by the discharge control circuit 2.

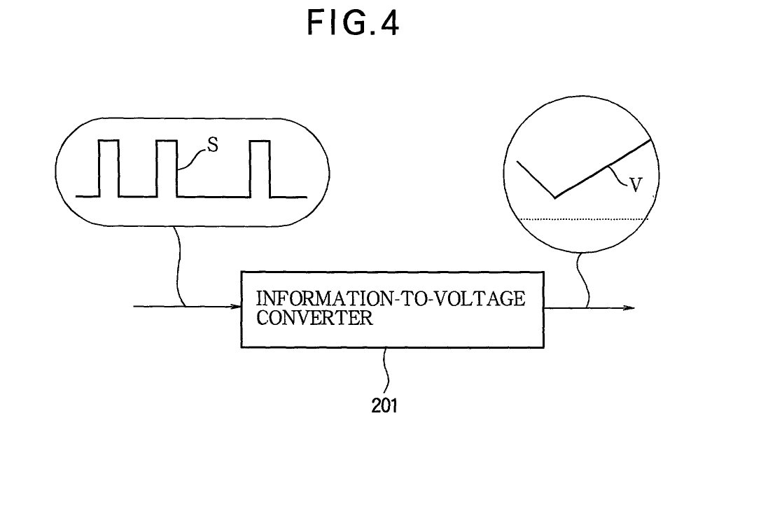

The discharge control circuit 2 generates the control signal V according to speed information S received from the vehicle, so as to make the resistance of the variable resistance unit decrease as the vehicle speed increases, thus as the expected rate of frame-to-frame level changes in the ASK signal increases. As shown in FIG. 4, the discharge control circuit 2 comprises an information-to-voltage converter 201, which is generally similar to the information-to-voltage converter in the first embodiment.

The information-to-voltage converter 201 generates the voltage V responsive to the speed information S from the vehicle, and supplies voltage V to the gate electrode of transistor FE1. The value of this voltage V increases with increasing vehicle speed. As the vehicle speed increases, accordingly, the resistance between the source and drain of transistor FE1 decreases.

The second embodiment operates in basically the same way as the first embodiment. The discharge resistance Rdis of capacitor C1 is given by the following equation, in which r3 and r4 are the resistance values of resistors R3 and R4, and rds is the drain-source resistance of transistor FE1.

Rdis={r3×(r4+rds)}/(r3+r4+rds)

The discharge time constant Tdis of capacitor C1 is given by the following equation, in which c1 is the capacitance of capacitor C1.

Tdis=c1×{r3×(r4+rds)}/(r3+r4+rds)

As explained above, the information-to-voltage converter 201 in the discharge control circuit 2 supplies a voltage V, responsive to the speed information received from the vehicle, to the gate electrode of transistor FE1, thereby controlling the drain-source resistance (rds) of transistor FE1 and the discharge resistance Rdis and discharge time Tdis of capacitor C1. If transistor FE1 is an ideal field-effect transistor, Rdis and Tdis vary within the following ranges, both decreasing as the vehicle speed increases and increasing as the vehicle speed decreases.

(r3×r4)/(r3+r4)≦Rdis≦r3

c1×(r3×r4)/(r3+r4)≦Tdis≦c1×r3

Therefore, when the vehicle is moving rapidly and the level of the ASK signal tends to vary greatly from one frame to the next, capacitor C1 discharges comparatively quickly. Conversely, when the vehicle is moving slowly and the level of the ASK signal is less variable from one frame to the next, capacitor C1 discharges comparatively slowly.

By providing the variable resistance unit and a discharge control circuit 2 that generates a control signal V responsive to the vehicle speed, accordingly, the second embodiment enables the discharge time constant Tdis of capacitor C1 to decrease as the amount of frame-to-frame variation in the ASK signal level increases. The time constant Tdis can therefore be set to the optimal value (the maximum value enabling frame-to-frame variations to be tracked) for all vehicle speeds, if suitable resistance values are selected and the control signal is generated in a suitable way. Optimal receiving characteristics can thus be obtained at all vehicle speeds.

By using a field-effect transistor FE1 instead of a bipolar transistor, the second embodiment also enables the structure of the discharge control circuit 2 to be simplified, since it is not necessary to convert the voltage V to a current signal. Specifically, the voltage-to-current converter 102 of the first embodiment (shown in FIG. 2) is not needed.

In a variation of the second embodiment, resistor R3 is eliminated (r3=∞), so that the discharge resistance Rdis of capacitor C1 varies in the following range.

r4≦Rdis≦

Alternatively, resistor R4 may be eliminated (r4=0), so that the discharge resistance Rdis of capacitor C1 varies in the following range.

0≦Rdis≦r3

Both resistors R3 and R4 may be eliminated, in which case the discharge resistance Rdis of capacitor C1 varies in the following range.

0≦Rdis≦

In these variations, the resistance of the variable resistance unit is still responsive to the vehicle speed. If resistor R4 is eliminated, since the discharge resistance can be reduced to substantially zero, capacitor C1 can be allowed to discharge very quickly at high vehicle speeds.

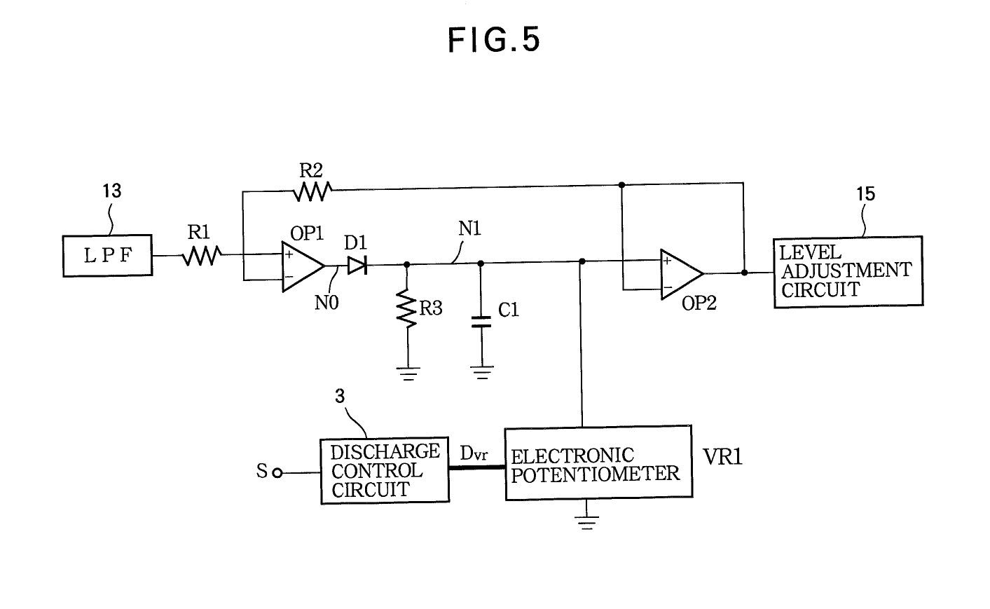

The third embodiment is the peak-hold circuit shown in FIG. 5, which can also be used as the peak-hold circuit 14 in the AGC circuit in FIG. 17.

The capacitor C1, diode D1, input amplifier OP1, output amplifier OP2, and resistors R1, R2, R3 in FIG. 5 are similar to the corresponding elements in FIG. 1. The discharge control circuit 3 in FIG. 5 controls an electronic potentiometer VR1 that forms the variable resistance unit. This peak-hold circuit is derived from the conventional peak-hold circuit 10 by adding the variable resistance unit and the discharge control circuit 3. It is also derivable from the first embodiment by replacement of the bipolar transistor TR1 and resistor R4 with the electronic potentiometer VR1, and by a modification of the discharge control circuit.

The electronic potentiometer VR1 is coupled in parallel with capacitor C1 and resistor R3 between node N1 and ground. The electronic potentiometer VR1 has a control terminal that receives control data Dvr (constituting a digital control signal) from the discharge control circuit 3. The control signal Dvr may be received as either a parallel or a serial data signal. The electronic potentiometer VR1 provides a variable resistance between node N1 and ground, the resistance varying in response to the input control signal Dvr.

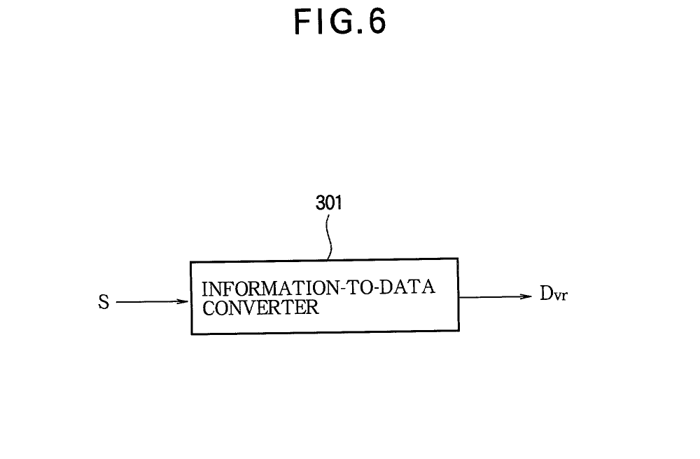

As shown in FIG. 6, the discharge control circuit 3 comprises an information-to-data converter 301. The information-to-data converter 301 generates the digital control signal Dvr according to the vehicle speed information S received from the vehicle, and supplies Dvr as control data to the control terminal of the electronic potentiometer VR1. The discharge control circuit 3 generates the control signal Dvr so that as the vehicle speed, and thus the expected rate of frame-to-frame variations in the ASK signal, increases, the resistance provided by the electronic potentiometer VR1 decreases. For example, if the electronic potentiometer VR1 provides increasing resistance as the value of the control data Dvr increases, then the discharge control circuit 3 reduces the value of the control data Dvr with increasing vehicle speed. Conversely, if the electronic potentiometer VR1 provides decreasing resistance as the value of the control data Dvr increases, then the discharge control circuit 3 increases the value of the control data Dvr with increasing vehicle speed.

The third embodiment operates in basically the same way as the first embodiment. The discharge resistance Rdis of capacitor C1 is given by the following equation, in which r3 is the resistance value of resistor R3 and vrl is the resistance of the electronic potentiometer VR1.

Rdis=(r3×vrl)/(r3+vrl)

The discharge time constant Tdis of capacitor C1 is given by the following equation, in which c1 is the capacitance of capacitor C1.

Tdis=c1×(r3×vrl)/(r3+vrl)

As explained above, in the discharge control circuit 3, the information-to-data converter 301 generates the control data Dvr according to the speed information S received from the vehicle. The data Dvr are output to the electronic potentiometer VR1 as a control signal. As a result, the resistance vr1 provided by the electronic potentiometer VR1 between node N1 and ground decreases with increasing vehicle speed.

If the electronic potentiometer VR1 has a resistance range from zero ohms to infinity, then the discharge resistance Rdis and discharge time constant Tdis of capacitor C1 can vary in the following ranges.

0≦Rdis≦r3

0≦Tdis≦c1×r3

Therefore, when the vehicle is moving rapidly and the level of the ASK signal can be expected to vary greatly from one frame to the next, capacitor C1 discharges comparatively quickly. Conversely, when the vehicle is moving slowly and the level of the ASK signal is unlikely to vary greatly from one frame to the next, capacitor C1 discharges comparatively slowly.

By providing the electronic potentiometer VRl and a discharge control circuit 3 that generates a control signal Dvr responsive to the vehicle speed, accordingly, the third embodiment enables the discharge time constant Tdis of capacitor C1 to decrease as the rate of frame-to-frame variation in the ASK signal level increases. The time constant Tdis can therefore be set to the optimal value (the maximum value enabling frame-to-frame variations to be tracked) for all vehicle speeds, if the control signal Dvr is generated in a suitable way. Optimal receiving characteristics can thus be obtained at all vehicle speeds.

By using an electronic potentiometer VR1, the third embodiment enables the structure of the discharge control circuit 3 to be simplified, since it is not necessary to convert a voltage to a current signal. In addition, the electronic potentiometer VR1 can provide a resistance value of substantially zero, so when necessary, capacitor C1 can be discharged very quickly.

In a variation of the third embodiment, resistor R3 is eliminated (r3=∞), so that the discharge resistance Rdis of capacitor C1 varies in the following range.

0≦Rdis≦∞

Alternatively, a resistor R4 may be inserted between the electronic potentiometer VR1 and ground. If the resistance value of this resistor is r4, the discharge resistance Rdis of capacitor C1 varies in the following range.

(r3×r4)/(r3+r4)≦Rdis≦r3

If resistor R4 is inserted in this position and resistor R3 is eliminated, the discharge resistance Rdis of capacitor C1 varies in the following range.

r4≦Rdis≦∞

In these variations, the resistance of the variable resistance unit is still responsive to the vehicle speed, so similar effects are obtained.

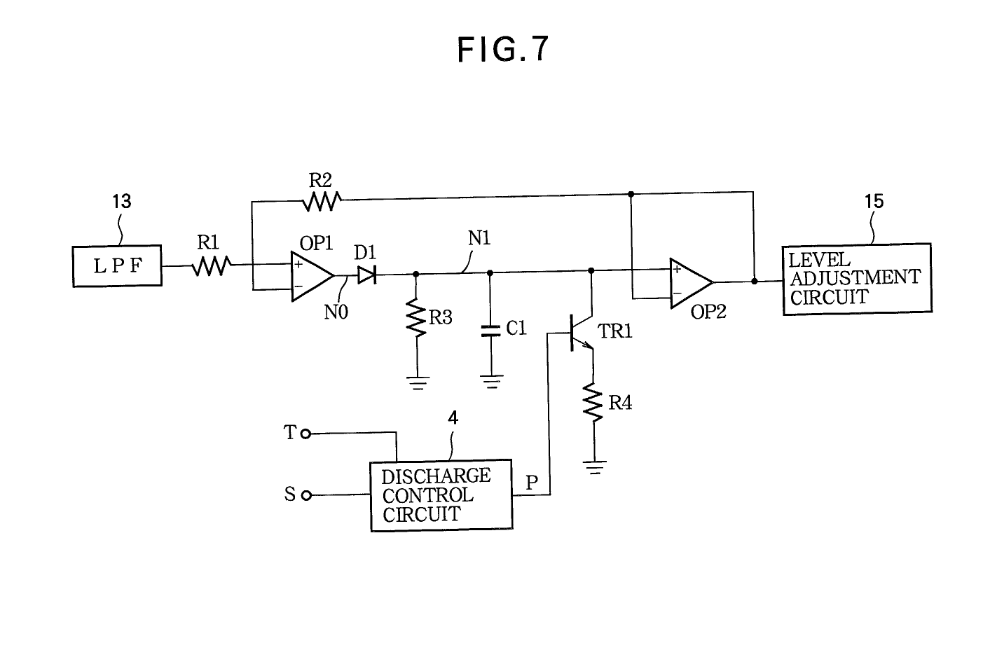

The fourth embodiment is the peak-hold circuit shown in FIG. 7, which can also be used as the peak-hold circuit 14 in the AGC circuit in FIG. 17.

The capacitor C1, diode D1, input amplifier OP1, output amplifier OP2, bipolar transistor TR1, and resistors R1, R2, R3, R4 in FIG. 7 are similar to the corresponding elements in FIG. 1. The bipolar transistor TR1 and resistor R4 now constitute a discharge unit. Transistor TR1 is controlled by a discharge control circuit 4 that receives both vehicle speed information S and frame timing information T. This peak-hold circuit is derived from the conventional peak-hold circuit 10 by adding the discharge unit and the discharge control circuit 4. It is also derivable from the first embodiment by modification of the discharge control circuit.

The discharge unit (bipolar transistor TR1 and resistor R4) is coupled in parallel with capacitor C1 and resistor R3 between node N1 and ground. In the discharge unit, transistor TR1 has its collector electrode coupled to node N1, its emitter electrode coupled through resistor R4 to ground, and its base electrode coupled to receive current pulses P from the discharge control circuit 4. These current pulses P will be referred to below as discharge pulses. Transistor TR1 turns on during each discharge pulse, and is switched off at other times. During a discharge pulse, capacitor C1 can discharge through resistor R4 to ground. At other times, this discharge path is opened (cut off).

Operating according to the frame timing information T, the discharge control circuit 4 generates one discharge pulse P in each interval between ASK frames. The width of the discharge pulses P is varied according to the vehicle speed information S.

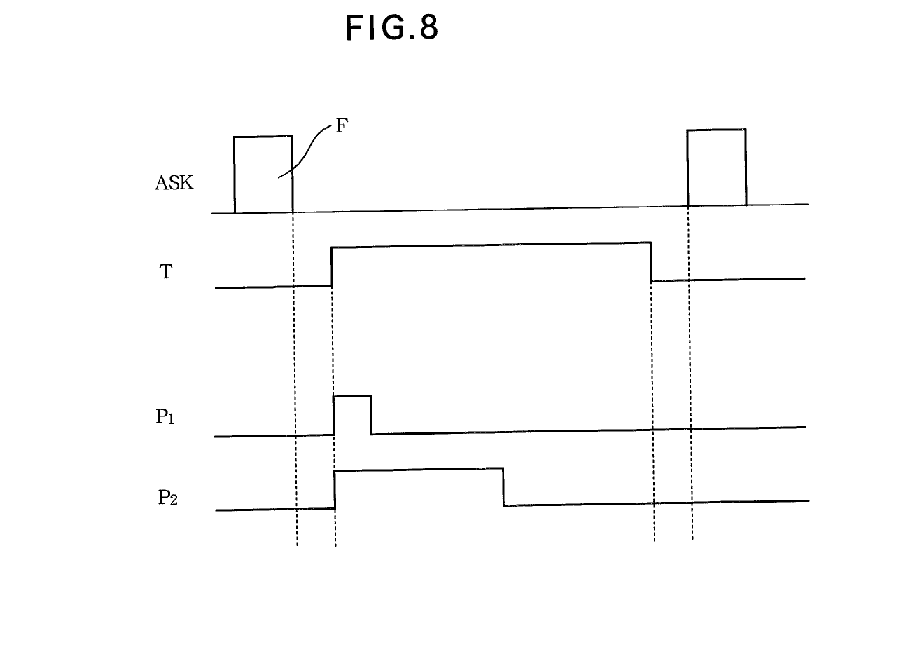

The operation of the discharge control circuit 4 is illustrated in FIG. 8, which shows waveforms of the ASK signal, the corresponding frame timing information T received by the discharge control circuit 4, and discharge pulses P₁ and P₂ output by the discharge control circuit 4 for different vehicle speeds.

The frame timing information T is received as, for example, a digital signal that goes high in the intervals between ASK frames F, as shown in FIG. 8. This signal T is obtained from the control unit of the on-board radio equipment (not shown in the drawings). The control unit generates this timing signal according to the ASK communication protocol, which prescribes the lengths of the frames and the lengths of the intervals between them.

As shown in FIG. 8, the discharge control circuit 4 initiates a discharge pulse P₁ or P₂ when the frame timing signal T goes high. The width of the discharge pulse depends on the vehicle speed, and increases as this speed increases. Discharge pulse P₁ is generated for a comparatively slow vehicle speed. Discharge pulse P₂ is generated for a comparatively high vehicle speed.

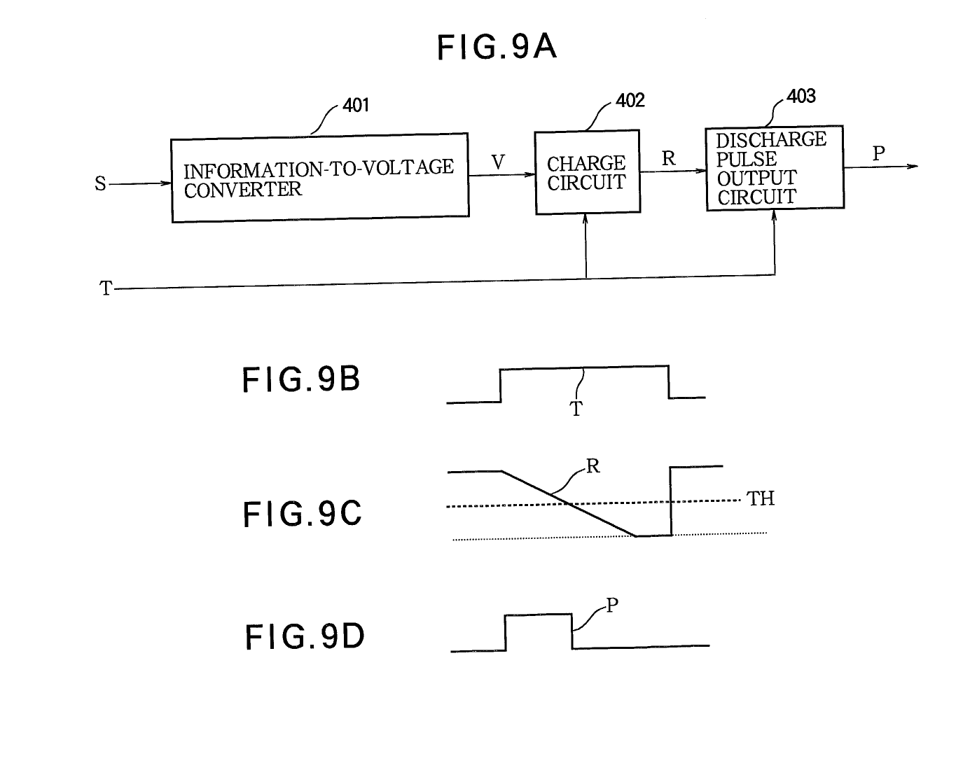

As shown in FIG. 9A, the discharge control circuit 4 comprises an information-to-voltage converter 401, a charge circuit 402, and a discharge pulse output circuit 403. FIGS. 9B, 9C, and 9D show waveforms of the frame timing information T, a voltage ramp signal R output by the charge circuit 402, and a discharge pulse P.

The information-to-voltage converter 401 generates a voltage V responsive to the vehicle speed information S, and supplies this voltage V to the charge circuit 402.

The charge circuit 402 comprises, for example, an internal capacitor, an internal resistor, and a pair of switches (not visible) controlled by the frame timing signal T. When the frame timing signal T is low, the internal capacitor is charged by the voltage V received from the information-to-voltage converter 401. When the frame timing signal T goes high, charging is terminated, and the internal capacitor is allowed to discharge through the internal resistor. The capacitor potential is output as the voltage ramp signal R. As illustrated in FIG. 9C, during the interval in which the frame timing signal T is high, the ramp signal R falls from the voltage level V to substantially zero volts.

The discharge pulse output circuit 403 generates the discharge pulse P by comparing the voltage ramp signal R with a predetermined threshold value indicated as dotted line TH in FIG. 9C. When the frame timing signal T is high, if the voltage level of the voltage ramp signal R is equal to or greater than the threshold level TH, the discharge pulse output circuit 403 drives the discharge pulse signal P to the high level. At other times (when T is low, or R is less than TH) the discharge pulse signal P is low. Thus the discharge pulse output circuit 403 supplies the base electrode of transistor TRI with a current pulse P during the first part of each interval between ASK frames, as indicated by the frame timing signal T. The higher the voltage V, the longer it takes the voltage ramp signal R to reach the threshold level TH, so the width of the pulse P increases with the voltage V, thus increasing with increasing vehicle speed.

In this embodiment, as in the first embodiment, the discharge resistance Rdis and discharge time constant Tdis of capacitor C1 are given by the following equations, in which r3 and r4 are the resistance values of resistors R3 and R4, and rec is the emitter-collector resistance of transistor TR1.

Rdis={r3×(r4+rec)}/(r3 r4 rec)

Tdis=c1×{r3×(r4+rec)}/(r3+r4+rec)

If transistor TR1 is an ideal bipolar transistor, its emitter-collector resistance is substantially zero (rec=0) during each discharge pulse (when P is high), and is substantially infinite (rec=∞) at other times (when P is low).

The fourth embodiment accordingly operates as follows. When an ASK frame is received, the potential of the input signal to the peak-hold circuit rises and diode D1 turns on. Capacitor C1 is rapidly charged and soon reaches the peak potential of the input signal in the ASK frame. This peak potential is held at node N1, and output to the level adjustment circuit 15 by the output amplifier OP2.

During the ASK frame, since no discharge pulse is output from the discharge control circuit 4 to the base electrode of transistor TR1, transistor TR1 remains in the off state, so its emitter-collector resistance remains substantially infinite (rec=∞) and capacitor C1 cannot discharge through the discharge unit formed by transistor TR1 and resistor R4.

During the ASK frame, accordingly, capacitor C1 has the following discharge resistance Rdisl and discharge time constant Tdis1.

Rdis1=r3

Tdis1=c1×r3

After the end of the ASK frame, the potential of the input signal quickly falls and remains low, diode D1 stays turned off, and capacitor C1 discharges, causing the potential of node N1 to fall. During part of the interval between the end of this ASK frame and the beginning of the next ASK frame, transistor TR1 receives a discharge pulse from the discharge control circuit 4 and turns on, c1osing the discharge path through the discharge unit. During the discharge pulse, the emitter-collector resistance of transistor TR1 is substantially zero (rec=0), so capacitor C1 discharges through both resistor R3 and the discharge unit (bipolar transistor TR1 and resistor R4). During the other part of the interval between ASK frames, when no discharge pulse is output, the emitter-collector resistance of transistor TR1 remains substantially infinite (rec=∞), and capacitor C1 discharges only through resistor R3.

During the discharge pulse, when the emitter-collector resistance (rec) is zero, capacitor C1 has the following discharge resistance Rdis2 and discharge time constant Tdis2.

Rdis2=(r3×r4)/(r3+r4)<Rdisl

Tdis2=c1×(r3×r4)/(r3+r4)<Tdis1

During the time when the discharge pulse is not output from the discharge control circuit 4, the discharge resistance and discharge time constant of capacitor C1 have the same values (Rdis1 and Tdis1) as during an ASK frame.

During the interval between ASK frames, accordingly, capacitor C1 first discharges rapidly through the discharge unit and resistor R3, with time constant Tdis2, then continues to discharge more slowly through resistor R3 alone, with time constant Tdisl. Moreover, the length of the rapid-discharge interval (the width of the discharge pulse P) increases with increasing vehicle speed. Accordingly, the total amount of discharge that takes place between ASK frames increases with increasing vehicle speed.

With suitable selection of the resistance values of resistors R3 and R4 and the threshold value TH, the time constants Tdis1 and Tdis2 and the width of the discharge pulse P can be set so that at any vehicle speed, capacitor C1 discharges sufficiently to track the largest downward variations in ASK signal level that may occur between frames, without discharging by an unnecessarily large amount. This scheme enables the peak-hold circuit to track frame-to-frame variations even at high vehicle speeds, without consuming unnecessary current at low vehicle speeds.

In addition, time constant Tdis1 can be given an arbitrarily high value, since Tdis2 can be made low to compensate. A high value of time constant Tdis1 enables the peak-hold circuit to hold the peak level within an ASK frame with comparatively little droop during low data bits in the frame. The peak-hold circuit can accordingly output a very stable peak level during an ASK frame, and still discharge rapidly enough to be ready for a lower ASK signal level in the next frame, at any vehicle speed.

In a variation of this embodiment, resistor R3 is eliminated, so that capacitor C1 can discharge only through the discharge unit. If transistor TR1 is an ideal bipolar transistor, time constants Tdis1 and Tdis2 then have the following values.

Tdis1=∞

Tdis2=c1×r4

The substantially infinite value of Tdis1 ensures extremely stable peak-value output during ASK frames.

In another variation, resistor R4 is eliminated. If transistor TR1 is an ideal bipolar transistor, time constants Tdis1 and Tdis2 then have the following values.

Tdis1=c1×r3

Tdis2=0

The substantially zero value of Tdis2 allows capacitor C1 to discharge nearly instantaneously during each discharge pulse.

In another variation, both resistors R3 and R4 are eliminated. If transistor TR1 is an ideal bipolar transistor, time constants Tdis1 and Tdis2 have the following values.

Tdis1=∞

Tdis2=0

This variation combines extremely stable peak-value output with fast tracking and a simple structure.

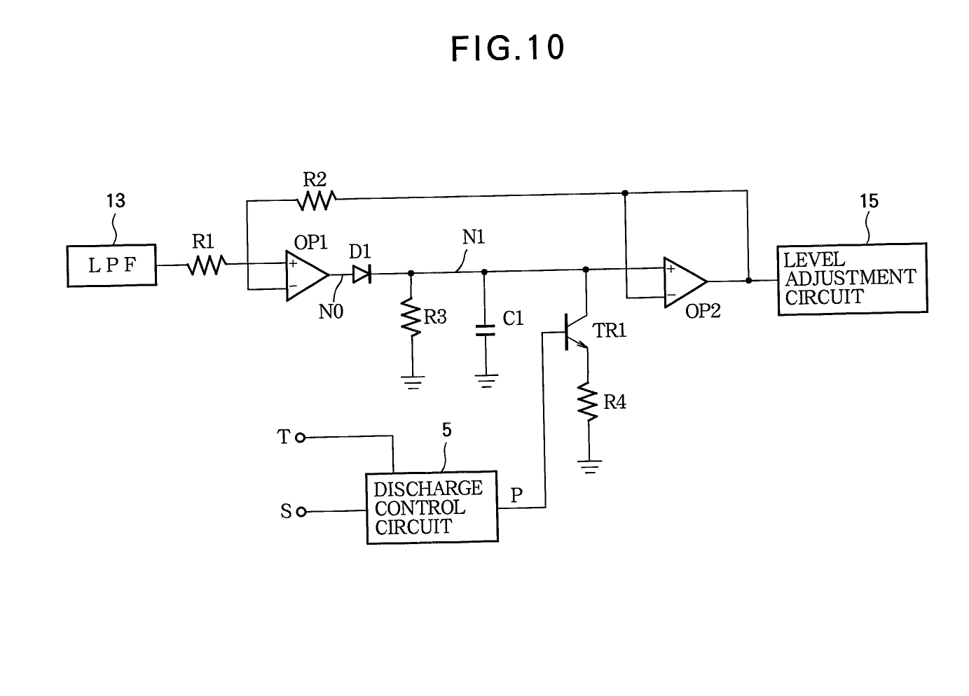

The fifth embodiment is the peak-hold circuit shown in FIG. 10, which can also be used as the peak-hold circuit 14 in the AGC circuit in FIG. 17.

The capacitor C1, diode D1, input amplifier OP1, output amplifier OP2, resistors R1, R2, R3, R4, and bipolar transistor TR1 in FIG. 10 are similar to the corresponding elements in FIG. 7. Transistor TR1 and resistor R4 constitute a discharge unit. The discharge control circuit 5 receives vehicle speed information S and frame timing information T and supplies discharge pulses P as current pulses to the base electrode of transistor TR1, but differs from the discharge control circuit 4 in FIG. 7, as described below. This peak-hold circuit is derived from the conventional peak-hold circuit 10 by adding the discharge unit and the discharge control circuit 5. It is also derivable from the fourth embodiment by modification of the discharge control circuit.

Operating according to the frame timing information T, the discharge control circuit 4 generates discharge pulses P in the intervals between ASK frames, varying the number of discharge pulses P in each interval according to the vehicle speed information S.

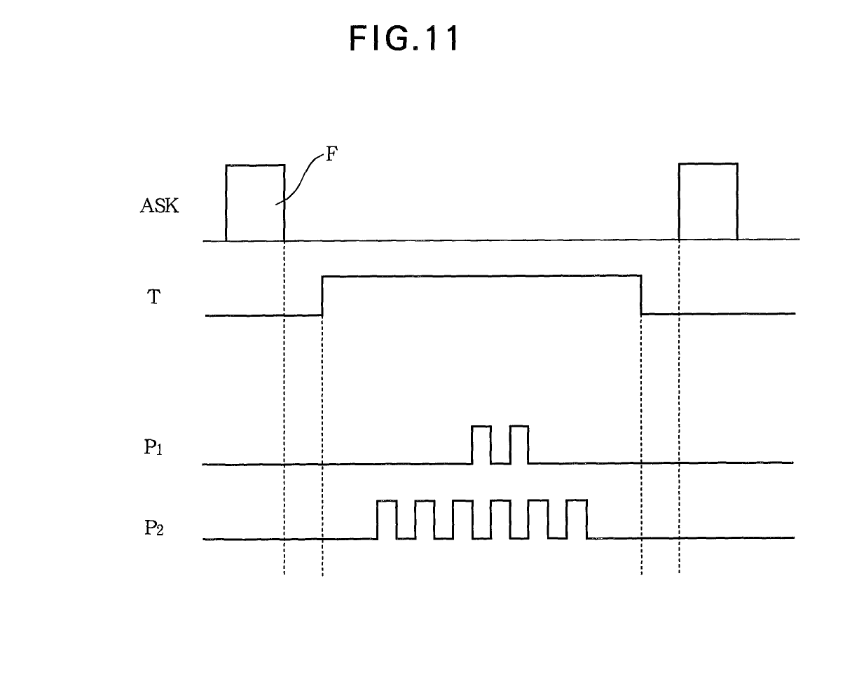

The operation of the discharge control circuit 5 is illustrated in FIG. 11, which shows waveforms of the ASK signal, the corresponding frame timing information T received by the discharge control circuit 5, and discharge pulses P₁ and P₂ output by the discharge control circuit 5 for different vehicle speeds. The frame timing information T is similar to the frame timing information in the fourth embodiment. The discharge pulses have constant width, but the number of discharge pulses output between a pair of ASK frames increases with increasing vehicle speed. Accordingly, P₁ is a discharge pulse waveform for a comparatively low vehicle speed, and P₂ is a discharge pulse waveform for a higher vehicle speed.

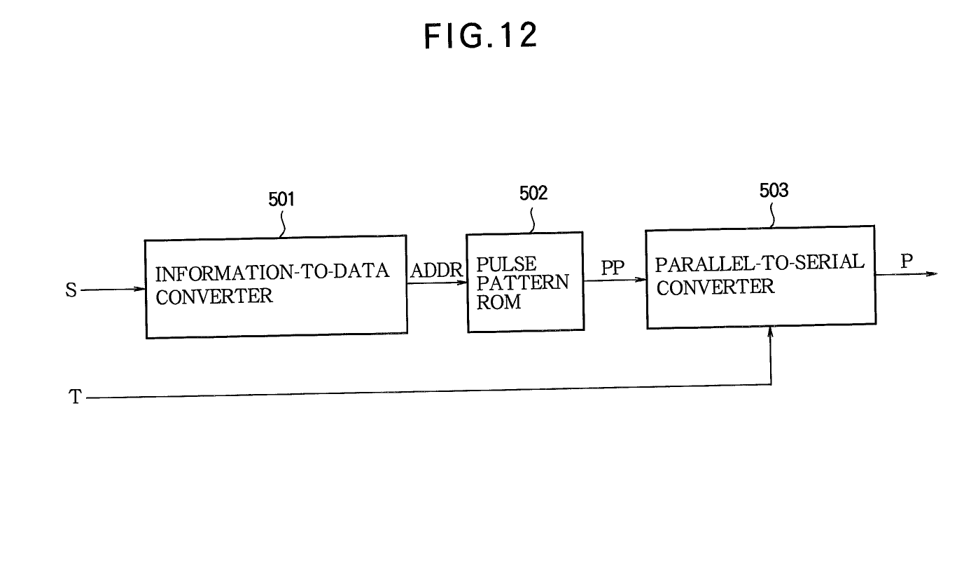

As shown in FIG. 12, the discharge control circuit 5 comprises an information-to-data converter 501, a pulse-pattern read-only memory (ROM) 502, and a parallel-to-serial converter 503.

The information-to-data converter 501 generates data indicative of the vehicle speed from the vehicle speed information S, and supplies the data as address data ADDR to the pulse pattern ROM 502.

The pulse pattern ROM 502 stores various bit patterns, representing pulse patterns, at addresses corresponding to different vehicle speeds. Patterns corresponding to higher vehicle speeds have more pulses, but the number of pulses is not necessarily proportional to the vehicle speed. The number and timing of the pulses can be set arbitrarily, simply by storing the appropriate bit data. The pattern stored at the address ADDR supplied by the information-to-data converter 501 is read out and supplied as parallel pulse data PP to the parallel-to-serial converter 503.

The parallel-to-serial converter 503 converts the parallel data PP received from the pulse pattern ROM 502 to serial data; that is, to a pulse pattern P such as P₁ or P₂ in FIG. 11. Output of the pulse pattern P to the base electrode of transistor TRl takes place during the interval in which the frame timing signal T is high, but output of the first pulse may occur at an arbitrary time in this interval.

The fifth embodiment operates in basically the same way as the fourth embodiment. Capacitor C1 discharges through resistor R3 with a first time constant Tdis1 during ASK frames, and at other times when no discharge pulse is supplied to transistor TR1, and discharges through resistor R3 and the discharge unit with a second and smaller time constant Tdis2 during output of discharge pulses P. The first time constant Tdisl is large enough to assure stable output during ASK frames. The second time constant Tdis2 is small enough to assure adequate discharging between ASK frames. The number of discharge pulses P increases with increasing vehicle speed to permit greater discharging at higher vehicle speeds.

More specifically, during ASK frames, the discharge resistance Rdis1 and time constant Tdis1 of capacitor C1 have the following values.

Rdis1=r3

Tdis1=c1×r3

During the discharge pulses that occur between ASK frames, the discharge resistance Rdis2 and discharge time constant Tdis2 of capacitor C1 have the following values.

Rdis2=(r3×r4)/(r3+r4)<Rdis1

Tdis2=c1×(r3×r4)/(r3+r4)<Tdis1

Since the number of discharge pulses output between each pair of ASK frames increases with increasing vehicle speed, capacitor C1 can discharge sufficiently to track large frame-to-frame variations in ASK signal level at high vehicle speeds, without having to discharge so much at lower vehicle speeds. The peak-hold circuit can thus track the ASK signal level at all vehicle speeds, without unnecessary current dissipation.

A further advantage of the fifth embodiment is that since a pulse pattern ROM 502 is used, the number and timing of the discharge pulses are unconstrained.

As in the fourth embodiment, resistor R3 can be eliminated, so that capacitor C1 discharges only through the discharge unit, in which case the time constants Tdis1 and Tdis2 have the following values.

Tdis1=∞

Tdis2=c1×r4

Similarly, resistor R4 can be eliminated, allowing capacitor C1 to discharge substantially instantaneously through the discharge unit. Time constants Tdis1 and Tdis2 then have the following values.

Tdis1=c1×r3

Tdis2=0

If both resistors R3 and R4 are eliminated, then time constants Tdis1 and Tdis2 have the following values.

Tdis1=∞

Tdis2=0

In another variation, the data stored in the pulse pattern ROM 502 provide discharge pulses of different pulse widths, as in the fourth embodiment, instead of different numbers of discharge pulses.

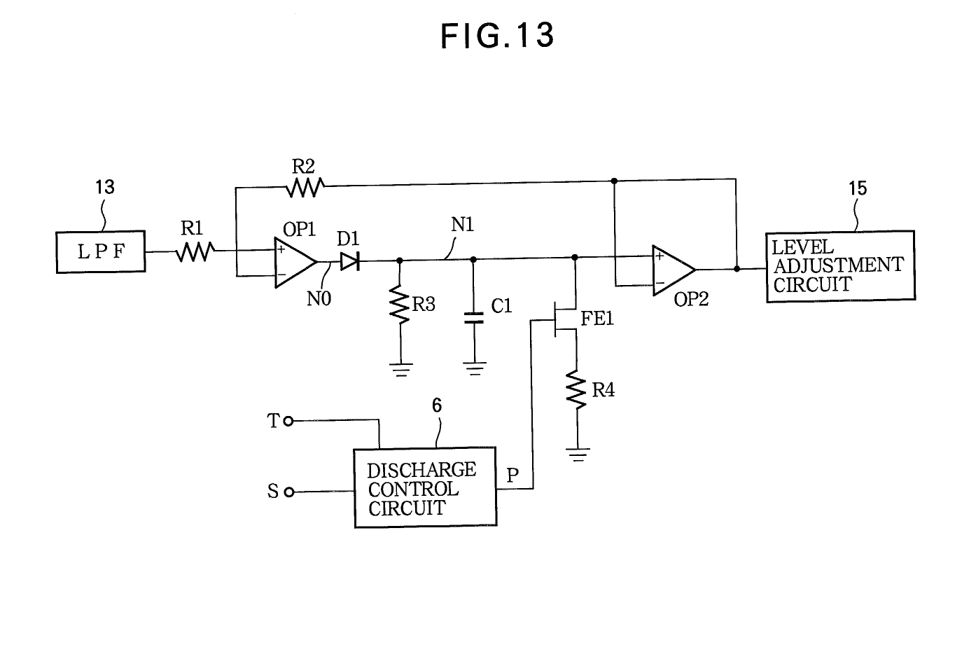

The sixth embodiment is the peak-hold circuit shown in FIG. 13, which can also be used as the peak-hold circuit 14 in the AGC circuit in FIG. 17.

The capacitor C1, diode D1, input amplifier OP1, output amplifier OP2, and resistors R1, R2, R3, R4 in FIG. 13 are similar to the corresponding elements in FIG. 7. The discharge control circuit 6 in FIG. 13 controls a field-effect transistor FE1 that, together with resistor R4, constitutes the discharge unit. This peak-hold circuit is derived from the conventional peak-hold circuit 10 by adding the discharge unit and the discharge control circuit 6. It is also derivable from the second embodiment by modification of the discharge control circuit.

The discharge unit (field-effect transistor FE1 and resistor R4) is coupled in parallel with capacitor C1 and resistor R3 between node N1 and ground. In the discharge unit, transistor FE1 has its drain electrode coupled to node N1, its source electrode coupled through resistor R4 to ground, and its gate electrode coupled to receive a discharge pulse signal P (a voltage signal) from the discharge control circuit 6. Transistor FE1 turns on during each discharge pulse, and is switched off at other times. During a discharge pulse, capacitor C1 can discharge through resistor R4 to ground. At other times, this discharge path is opened (cut off).

The discharge control circuit 6 is similar to the discharge control circuit 4 in the fourth embodiment, generating one discharge pulse P in each interval between two ASK frames, the width of the pulse increasing with increasing vehicle speed, as illustrated in FIG. 8.

The sixth embodiment operates in basically the same way as the fourth embodiment. During input of an ASK frame, capacitor C1 discharges through resistor R3 with a comparatively large discharge time constant Tdis1, ensuring output of a stable peak level. During the discharge pulse generated between a pair of ASK frames, capacitor C1 discharges through both resistor R3 and the discharge unit (field-effect transistor FE1 and resistor R4), with a smaller time constant Tdis2, so that frame-to-frame variations in ASK signal level can be tracked. The amount of discharge increases with increasing vehicle speed, so that unnecessary discharge does not take place at low vehicle speeds.

Compared with the fourth embodiment, use of the field-effect transistor FE1 in the sixth embodiment reduces current consumption. The structure of the discharge control circuit 6 can be simplified in that less output driving capability is required.

The sixth embodiment can be modified by eliminating resistor R3 (so that r3=∞), eliminating resistor R4 (so that r4=0), or eliminating both resistors R3 and R4.

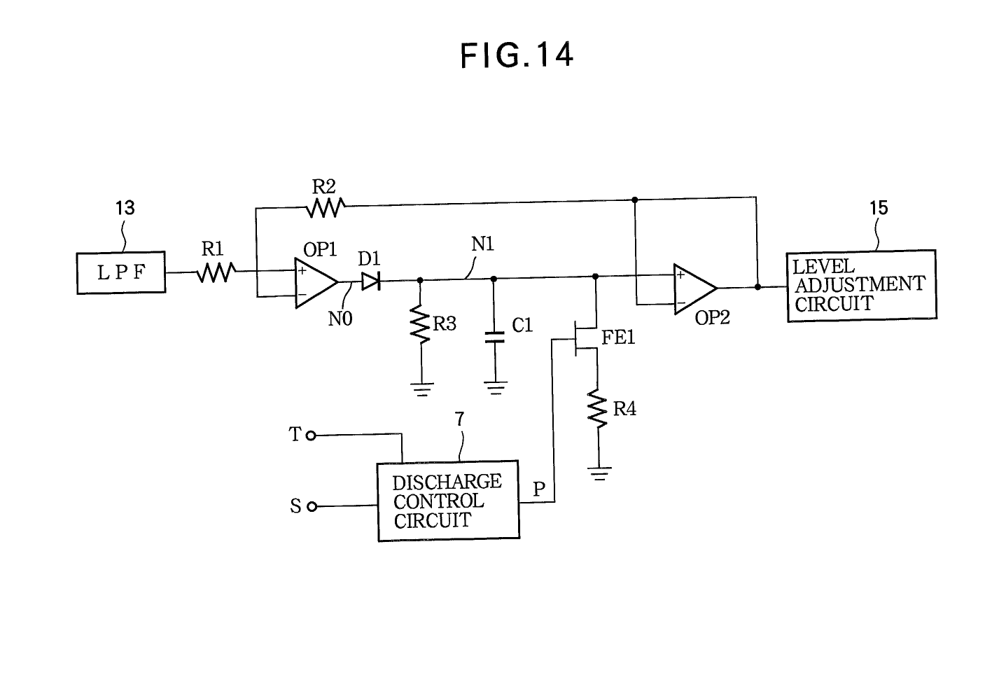

The seventh embodiment is the peak-hold circuit shown in FIG. 14, which can also be used as the peak-hold circuit 14 in the AGC circuit in FIG. 17.

The capacitor C1, diode D1, input amplifier OP1, output amplifier OP2, resistors R1, R2, R3, R4, and field-effect transistor FE1 in FIG. 14 are similar to the corresponding elements in FIG. 13. The discharge control circuit 7 is similar to the discharge control circuit 5 in FIGS. 10 and 12. This peak-hold circuit is derived from the conventional peak-hold circuit 10 by adding the discharge unit (field-effect transistor FE1 and resistor R4) and the discharge control circuit 6. It is also derivable from the sixth embodiment by modification of the discharge control circuit.

The discharge control circuit 7 operates as shown in FIG. 11, generating a number of discharge pulses P that increases with increasing vehicle speed. The discharge pulses P are now voltage pulses.

The seventh embodiment operates in basically the same way as the fifth embodiment. During input of an ASK frame, capacitor C1 discharges through resistor R3 with a comparatively large discharge time constant Tdis1, ensuring output of a stable peak level. During the discharge pulses generated between a pair of ASK frames, capacitor C1 discharges through both resistor R3 and the discharge unit (field-effect transistor FE1 and resistor R4), with a smaller time constant Tdis2, so that frame-to-frame variations in ASK signal level can be tracked. The amount of discharge increases with increasing vehicle speed, so that unnecessary discharge does not take place at low vehicle speeds.

Compared with the fifth embodiment, use of the field-effect transistor FE1 in the seventh embodiment reduces current consumption. The structure of the discharge control circuit 7 can be simplified, since less output driving capability is required.

The seventh embodiment can be modified by eliminating resistor R3 (so that r3=∞), eliminating resistor R4 (so that r4=0), or eliminating both resistors R3 and R4.

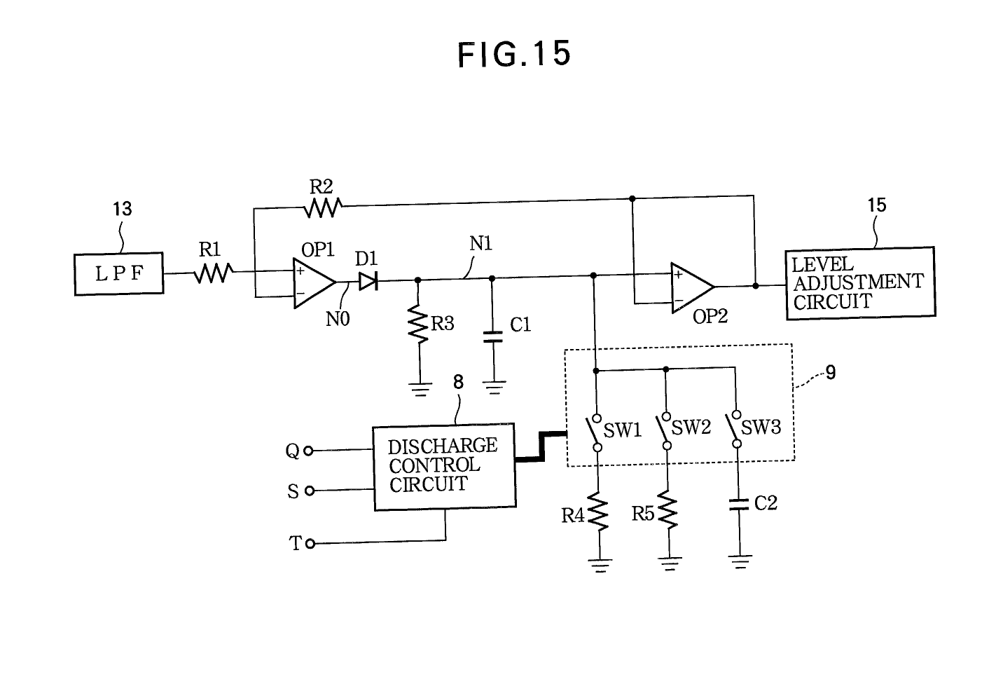

The eighth embodiment is the peak-hold circuit shown in FIG. 15, which can also be used as the peak-hold circuit 14 in the AGC circuit in FIG. 17.

The capacitor C1, diode D1, input amplifier OP1, output amplifier OP2, and resistors R1, R2, R3 are similar to the corresponding elements in FIG. 1. The discharge control circuit 8 controls an analog switch circuit 9, which is coupled to node N1. Further resistors R4, R5 and a capacitor C2 are coupled between the analog switch circuit 9 and ground. The analog switch circuit 9 and these resistors R4, R5 and capacitor C2 constitute a discharge unit. This peak-hold circuit is derived from the conventional peak-hold circuit 10 by adding the discharge unit and the discharge control circuit 8.

The analog switch circuit 9 comprises three analog switches SW1, SW2, SW3. One terminal of each analog switch SW1, SW2, SW3 is coupled to node N1. The other terminals of these analog switches SW1, SW2, SW3 are coupled, respectively, to resistor R4, resistor R5, and capacitor C2. Capacitor C2 has a higher capacitance than capacitor C1. Resistors R4 and R5 may have arbitrary resistance values, not necessarily equal.

The discharge control circuit 8 supplies the analog switch circuit 9 with digital signals that control the three analog switches. Analog switch SW1 turns on and off according to a first control signal, coupling resistor R4 to node N1 when in the on state. Analog switch SW2 turns on and off according to a second control signal, coupling resistor R5 to node N1 when in the on state. Analog switch SW3 turns on and off according to a third control signal, coupling capacitor C2 to node N1 when in the on state.

The discharge control circuit 8 generates these control signals by operating according to vehicle speed information S, frame timing information T, and charge command information Q. More specifically, the discharge control circuit 8 turns analog switches SW1 and SW2 on at selected times during the intervals between ASK frames, and turns analog switch SW3 on at selected times when analog switches SW1 and SW2 are turned off. When either analog switch SW1 or SW2 is turned on, a discharge path is closed, permitting capacitor C1 to discharge through the discharge unit. When analog switch SW3 is turned on during an ASK frame, capacitor C2 is charged to the same peak potential as capacitor C1. The peak potential is then stored in capacitor C2 while analog switch SW3 is off, and can be restored from capacitor C2 to node N1 later.

The discharge control circuit 8 controls analog switches SW1 and SW2 according to the vehicle speed information S. Various control schemes are possible: for example, both analog switches SW1 and SW2 can be turned on at high vehicle speeds, only one analog switch (either SW1 or SW2) being turned on at lower vehicle speeds. In addition, the length of time for which analog switches SW1 and SW2 are turned on may depend on the vehicle speed. Alternatively, these analog switches may be turned on for repeated short intervals, in a pulsed fashion, and the number of intervals (pulses) may be varied according to the vehicle speed.

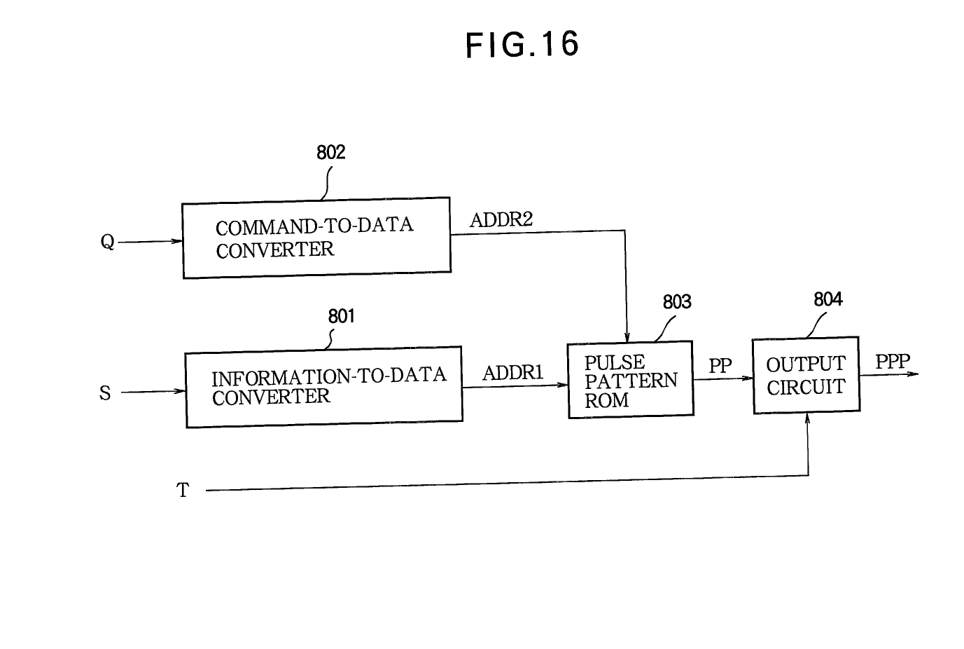

As shown in FIG. 16, the discharge control circuit 8 comprises an information-to-data converter 801, a command-to-data converter 802, a pulse pattern ROM 803, and an output circuit 804.

The information-to-data converter 801 converts the vehicle speed information S to corresponding data, and supplies these data as first address data ADDR1 to the pulse pattern ROM 803. The command-to-data converter 802 converts the charge command information Q to corresponding data and supplies these data as second address data ADDR2 to the pulse pattern ROM 803. The first address data ADDR1 select pulse patterns for controlling analog switches SW1 and SW2. The second address data ADDR2 select pulse patterns for controlling analog switch SW3. The charge command information Q indicates when the peak potential is to be stored in capacitor C2, and when the potential stored in capacitor C2 is to be restored to node N1. The charge command information Q may be generated within the discharge control circuit 8, or may be generated by a control unit (not visible) of the on-board radio equipment.

The pulse pattern ROM 803 stores pulse patterns PP at addresses specifiable by the combined address data ADDR1 and ADDR2. Each address holds three pulse patterns, one pattern for each of the three analog switches SW1, SW2, SW3. The pulse patterns indicate the times at which the analog switches SW1, SW, SW3 are to be switched on, and how long they are to remain on. These pulse patterns PP are supplied in parallel data form to the output circuit 804.

The output circuit 804 converts the parallel data received from the pulse pattern ROM 803 to three serial data signals (PPP) that control the analog switch circuit 9. The output of these serial control signals is synchronized with the frame timing signal T. For example, the first two control signals may turn on analog switch SW1 for a certain length of time during an interval between ASK frames, leaving analog switch SW2 off. The third control signal may turn analog switch SW3 on for a certain time during an ASK frame to store the peak potential, then turn analog switch SW3 on again for a certain time between ASK frames, while analog switches SW1 and SW2 are both off, to restore the stored potential to node N1. Alternatively, the first two control signals may turn analog switches SW1 and SW2 on repeatedly a certain number of times during an interval between ASK frames, and the third control signal may leave analog switch SW3 off during the ASK frames, so that the peak potential is not stored in capacitor C2.

The eighth embodiment operates as follows. When an ASK frame is first received, the potential of the input signal to the peak-hold circuit rises and diode D1 turns on. Capacitor C1 is rapidly charged and soon reaches the peak potential of the input signal in the ASK frame. This peak potential is held at node N1, and output to the level adjustment circuit 15 by the output amplifier OP2.

During the ASK frame, the output circuit 804 in the discharge control circuit 8 does not supply control signals to turn on analog switches SW1 and SW2, so capacitor C1 can discharge only through resistor R3. The discharge resistance Rdis1 and discharge time constant Tdis1 are as follows.

Rdis1=r3

Tdis1=c1×r3

During the ASK frame, the third control signal output from the discharge control circuit 8 may turn on analog switch SW3 for a certain time, during which capacitor C2 is charged to the same potential as node N1. This potential remains stored in capacitor C2 after analog switch SW3 is turned off.

After the end of the ASK frame, the potential of the input signal quickly falls and remains low, diode D1 stays turned off, and capacitor C1 discharges, causing the potential of node N1 to fall. If analog switch SW1 or SW2 is switched on, the discharge takes place through resistor R4 or resistor R5 as well as through resistor R3, and the discharge resistance and discharge time constant are reduced accordingly. For example, if analog switch SW1 is turned on while analog switch SW2 is left off, and if analog switch SW1 is an ideal analog switch, the discharge resistance Rdis2 and discharge time Tdis2 have the following values, r3 and r4 being the resistance value of resistors R3 and R4, and c1 the capacitance value of capacitor C1.

Rdis2 (r3×r4)/(r3+r4)<Rdis1

Tdis2=c1×(r3×r4)/(r3+r4)<Tdis1

As in the fourth embodiment, time constant Tdis2 is smaller than time constant Tdis1, allowing capacitor C1 to discharge more quickly during the intervals between ASK frames than within the ASK frames. As explained in the fourth embodiment, Tdis1 can be made large enough to assure stable peak-level output during ASK frames, while Tdis2 can be made small enough to ensure tracking of frame-to-frame variations in ASK signal level, and the time for which analog switches SW1 and SW2 are switched on can be controlled so as to avoid unnecessary current consumption. The availability of two analog switches SW1, SW2 and two resistors R4, R5 affords even more flexibility than in the fourth embodiment, however, in adapting the discharge time constant Tdis2 to different vehicle speeds.

In addition, during an interval between ASK frames, at a time when both analog switches SW1 and SW2 are off, analog switch SW3 can be turned on to restore node N1 to the peak potential of a former ASK frame.

To recapitulate the operation of the eighth embodiment, a discharge unit (comprising the analog switch circuit 9 and resistors R4, R5) is provided, in which additional discharge paths can be formed for capacitor C1. These additional discharge paths are closed only during the intervals between ASK frames, as indicated by the frame timing information T. During ASK frames, the additional discharge paths remain open. The discharge time constant of capacitor C1 can thus be reduced for selected periods of time during the intervals between ASK frames, to permit tracking of frame-to-frame variations in ASK signal level, while the discharge time constant Tdis1 during ASK frames is made high enough to assure stable peak-value output. Excellent receiving characteristics can thus be obtained.

Furthermore, the peak potential during an ASK frame can be stored in capacitor C2, so that node N1 can be restored to this potential after capacitor C1 has discharged.

The eighth embodiment can be modified by eliminating resistor R3 (so that r3=∞) In the discharge unit, analog switch SW3 and capacitor C2 can be eliminated. Analog switch SW1 and resistor R4 can likewise be eliminated. Alternatively, analog switch SW2 and resistor R5 can be eliminated. It is also possible to eliminate analog switch SW2 and both resistors R3 and R5 (so that r3=0 and r5=∞).

The embodiments above have been described in relation to a peak-hold circuit used for automatic gain control in on-board equipment in an electronic toll collection system, but the invention is not limited to this application; it can be usefully practiced in a variety of situations in which a signal is received in intermittent bursts and the peak value of each burst must be held.

Those skilled in the art will recognize that further variations are possible within the scope c1aimed below.

What is claimed is:

1. A peak-hold circuit receiving an input signal in intermittent bursts, for holding a peak level of the input signal during each one of the bursts, comprising:
a diode having a cathode and an anode, receiving the input signal at said anode;
a capacitor coupled between the cathode of the diode and ground, for holding said peak level;
a variable resistance unit coupled between the cathode of the diode and ground, providing an electrical resistance that varies according to a control signal; and
a discharge control unit receiving information indicating an expected rate of signal level variation of the input signal, and generating said control signal according to said information.

2. The peak-hold circuit of claim 1, wherein the discharge control unit uses said control signal to decrease the electrical resistance of the variable resistance unit as said expected rate of signal level variation increases.

3. The peak-hold circuit of claim 1, wherein the variable resistance unit inc1udes a bipolar transistor with a base electrode receiving said control signal.

4. The peak-hold circuit of claim 1, wherein the variable resistance unit inc1udes a field-effect transistor with a gate electrode receiving said control signal.

5. The peak-hold circuit of claim 1, wherein the variable resistance unit inc1udes an electronic potentiometer with a control terminal receiving said control signal as control data.

6. The peak-hold circuit of claim 1, further comprising a fixed resistor coupled between the cathode of said diode and ground.

7. A peak-hold circuit receiving an input signal in intermittent bursts, for holding a peak level of the input signal during each one of the bursts, comprising:
a diode having a cathode and an anode, receiving the input signal at said anode;
a first capacitor coupled between the cathode of the diode and ground, for holding said peak level;
a discharge unit coupled between the cathode of the diode and ground, opening and c1osing a discharge path for the first capacitor in response to a control signal; and
a discharge control unit receiving first information indicating timing of said intermittent bursts, and generating said control signal according to said first information, thereby controlling the discharge unit so that said discharge path is opened during said intermittent bursts.

8. The peak-hold circuit of claim 7, wherein the discharge unit inc1udes a bipolar transistor with a base electrode receiving said control signal.

9. The peak-hold circuit of claim 7, wherein the discharge unit inc1udes a field-effect transistor with a gate electrode receiving said control signal.

10. The peak-hold circuit of claim 7, wherein the discharge unit inc1udes an analog switch controlled by said control signal.

11. The peak-hold circuit of claim 7, wherein the discharge control unit also receives second information indicating an expected rate of signal level variation of the input signal, and also generates said control signal according to said second information, so that said discharge path is closed for increasing lengths of time between said intermittent bursts as said expected rate of signal level variation increases.

12. The peak-hold circuit of claim 11, wherein the discharge control unit generates said control signal as a pulse signal with a pulse width that increases as said expected rate of signal level variation increases.

13. The peak-hold circuit of claim 11, wherein the discharge control unit generates said control signal as a series of pulses, the number of said pulses increasing as said expected rate of signal level variation increases.

14. The peak-hold circuit of claim 11, wherein the discharge unit comprises:
a plurality of analog switches coupled in parallel between the cathode of said diode and ground, switched on and off by said control signal; and
a plurality of resistors coupled in series with respective ones of the analog switches between the cathode of said diode and ground.

15. The peak-hold circuit of claim 14, wherein the discharge control unit uses said control signal to switch on different numbers of the analog switches according to said second information.

16. The peak-hold circuit of claim 14, wherein the discharge control unit uses said control signal to switch the analog switches on for different lengths of time according to said second information.

17. The peak-hold circuit of claim 14, wherein the discharge control unit uses said control signal to switch the analog switches on for different numbers of times according to said second information.

18. The peak-hold circuit of claim 7, further comprising:
an analog switch coupled to the cathode of said diode, switched on and off by said control signal; and
a second capacitor coupled between said analog switch and ground, for storing said peak level.

19. The peak-hold circuit of claim 7, further comprising a fixed resistor coupled between the cathode of said diode and ground.
